(19) United States
(12) Patent Application Publication
(10) Pub. No.: US 2024/0396557 A1
(43) Pub. Date: Nov. 28, 2024

(54) Integrated Circuit Design for Digital Computing and Information Processing of Mechanical Signals

(71) Applicant: THE PENN STATE RESEARCH FOUNDATION, University Park, PA (US)

(72) Inventors: Ryan Lee Harne, Port Matilda, PA (US); Charles El Helou, State College, PA (US)

(21) Appl. No.: 18/695,915

(22) PCT Filed: Sep. 28, 2022
(86) PCT No.: PCT/US2022/044988

§ 371 Date: Mar. 27, 2024

Related U.S. Application Data
(60) Provisional application No. 63/249,084, filed on Sep. 28, 2021.

(51) Int. Cl. H03K 19/20

(52) U.S. Cl. CPC H03K 19/20

(57) ABSTRACT

A digital information processing device includes a soft material including a plurality of electrically conductive and electrically non-conductive regions. The soft material has a shape configuration configured to transform from an uncompressed configuration to fully compact configurations under an applied load. The electrically conductive regions form electrical networks that are in a closed or open state dependent upon the applied load acting on the soft material.

### REFERENCE TO RELATED APPLICATION

This application is the U.S. National Stage of PCT/US2022/044988 filed on Sep. 28, 2022, which claims priority from U.S. Provisional Patent Application Ser. No. 63/249,084, filed Sep. 28, 2021, the entire content of which is incorporated herein by reference.

### FIELD OF THE INVENTION

The present invention relates to digital information processing using soft materials that intrinsically respond to applied fields, including light, thermal gradients, mechanical load, electromagnetic waves, acoustic waves, humidity gradients, pH gradients, and/or other applied fields.

### BACKGROUND OF THE INVENTION

There is considerable interest to develop digital information processors that do not use conventional silicon microprocessor technology, and instead use only soft materials with low bulk modulus, such as less than 1 GPa (M. Pishvar, R. L. Harne, Foundations for soft, smart matter by active mechanical metamaterials, Advanced Science 7, 2001384 (2020)).

These “computers” would be amenable to integration in polymers and other soft materials, providing substantially greater mechanical robustness and durability for applications involving mechanical stress, shock, and other environments where energy or power resources are scarce. These “computers” would also be amenable to facilitating fully autonomous soft materials that “live” using only organic, inorganic, or synthetic materials, thus lacking biological matter.

The state-of-the-art in the field of information processing in soft materials has yielded elementary computing functions, such as basic logic gate operation (V. Dhasarathan, S. K. Sahu, T. K. Nguyen, G. Palai, Realization of all logic gates using metamaterials based three dimensional photonics structures: a future application of 3D photonics to optical computing, Optik-International Journal for Light and Electron Optics 202, 163723 (2020); Y. Jin, Y. Lin, A. Kiani, I. D. Joshipura, M. Ge, M. D. Dickey, Materials tactile logic via innervated soft thermochromic elastomers, Nature Communications 10, 4187 (2019); B. Xu, D. Chen, R. C. Hayward, Mechanically gated electrical switches by creasing of patterned metal/elastomer bilayer films, Advanced Materials 26, 4381-4385 (2014)).

It is found that the state-of-the-art does not lend itself to scalability, in the sense of creating integrated circuits from such soft material components. Integrated circuits are collections of logic gates in specific sequences, that together yield operations like “add two numbers”. “subtract two numbers”. “multiply two numbers”. “compare two numbers”, and more. These simple operations, and several others, in fact form the entirety of modern digital computation. Modern silicon microprocessors contain billions of logic gates, so that numerous integrated circuits are interfaced together yielding advanced information processing. This type of scalability is entirely lacking in the state-of-the-art in information with soft materials.

### SUMMARY OF THE INVENTION

Embodiments of the present invention provides digital information processing devices such as logic gates, integrated circuits, storage devices and methods of designing the same using soft materials that intrinsically respond to applied fields, including light, thermal gradients, mechanical load, electromagnetic waves, acoustic waves, humidity gradients, pH gradients, and/or other applied fields. The response may include but be not limited to shape transformation, change of volumes, or shape memory.

Soft materials are materials with low bulk modulus, such as less than 1 GPa. Soft material may include but not limited to organic materials, organic compounds, inorganic materials, inorganic compounds, polymers, elastomers, epoxy-based composites, fiber-based composites, synthetic materials and other biological materials.

In some embodiments, the soft material includes a plurality of electrically conductive and electrically non-conductive regions. The electrically conductive regions may be in the soft material, fully encapsulated by the soft material, on the soft material, and positioned elsewhere so that the electrically conductive regions have means to come in contact. The soft material has a shape or configuration configured to transform from an uncompressed configuration to fully compact configurations under an applied load. The electrically conductive regions form electrical networks that are closed or open dependent upon the applied load acting on the soft material. The closed or open state of the electrical networks corresponds to digital logic functioning that are in agreement with a preferred Boolean algebra function or arithmetic expression.

Applied load may be in the form of shear stress, mechanical force, mechanical pressure, thermomechanical loads, optomechanical loads, chemomechanical loads, electroactive material loads, and other body forces to yield the fully compact configurations of the device.

In some embodiments, the soft materials are prepared as a matrix of unit cells stacked and connected together with gaps. The surfaces or cross-sections of some of the unit cells serve as a substrate and are coated with traces of conductive soft materials. Conductive soft materials may include a composite mixture of a polymer or other aforementioned soft material filled with conductive filler material including carbon, gold, silver, copper, or other electrically conductive filler particles. The traces may also be fully encapsulated by the unit cells. The depth of the unit cells may or may not be used as a dimension of shape reconfiguration, and thus the depth may or may not be included as a design variable. In an uncompressed configuration, the traces of conductive materials do not form a continuous network for electrical conductivity. In fully compact configurations, the traces of conductive materials might or might not form an electrically conductive network depending on the ways that the matrix is compressed.

In one embodiment, all of the unit cells are connected without any discontinuities. In this case, when the matrix is uncompressed, the electrical network is open. When the matrix is compressed under an applied load, the matrix shifts the form into a fully compact self-contact configuration and the electrical network is in a closed connecting state and is conductive.

In some embodiments, some of the unit cells are connected and there are some discontinuities between some other unit cells. In this case, when the matrix is compressed under an applied load, the matrix transforms into a number of distinct fully compact configurations dependent on the applied load on different layers of the matrix. The distinct fully compact configurations match the circuit for switches, logic gates, storage devices or integrated circuits.

The applied load may cause counterclockwise or clockwise rotation of some of the unit cells due to the gaps and the discontinuities. Discontinuities serve as a mechanism to govern internal motion of adjacent unit cells and layers. Clockwise/counterclockwise rotations can each be assigned a digital value serving as binary digital inputs. The design of the traces of the electrically conductive material and the configuration of the matrix including the manners that the unit cells are stacked and the locations of the discontinuities and are designed in a way such that when the matrix is compressed, the output of the electrical network is in agreement with the corresponding output of the switches, logic gates, storage devices or circuit assemblies based on corresponding Boolean functions. Examples of the switches include BUFFER and NOT, etc. Examples of the logic gates include AND, OR, NOR, XOR, etc. Examples of the integrated circuits include an adder, multiplier, subtractor, comparator, decoder, etc.

In some embodiments, all of the unit cells are uniform so the stress applied on each layer will be uniform.

In some embodiments, the matrix is designed to include a number of columns and rows. The alternating rows are designed to be rotating layers including discontinuities.

In some embodiments, the logic gates or the integrated circuits can all be made using only BUFFER switches and NOT switches based on the standard sum of product (SSoP) formulation. The numbers of the rotating layers should be equal to the number of inputs. The number of columns should be equal to the number of minterms in the SSoP formulations. The switches in the same column are connected in series. All of the columns are then connected in parallel.

In some embodiments, the electrical network is an elemental switch such as BUFFER or NOT switches. Counterclockwise/clockwise rotations of the unit cells in a layer will result in two possible fully compact self-contact configurations. Counterclockwise/clockwise rotations of the unit cells correspond to one-bit binary digital inputs. The two fully compact self-contact configurations correspond to open or closed states of the electrical switches which correspond to binary digital outputs. The counterclockwise rotation is induced by mechanical shear to the left, while shear to the right induces the clockwise rotation of the unit cells.

In some embodiments, the unit cells are connected together in a configuration of stacked elemental switches with periodic gaps and with discontinuities and two rotating layers corresponding to 2-bit binary inputs. 2-bit binary inputs are based on (counter) clockwise assignment of binary digital bits for the rotating layers. There are 4 buckling modes due to a combination of clockwise rotation and counterclockwise rotation of rotating layers. The four fully compact self-contact configurations correspond to binary digital outputs, the binary digital outputs correspond to variable open or closed states of the electrical network representative of Boolean operations of logic gates.

In some embodiments, the digital information processing device includes a soft material substrate and an electrically conductive soft material layer disposed on the substrate and the soft material responds to applied stresses by creating a variable connecting electrical network having a variable connecting configuration, in agreement with a preferred Boolean algebra function or arithmetic expression.

### BRIEF DESCRIPTION OF THE DRAWINGS

FIG. 1A shows a compliant conductive mechanical metamaterial switch in accordance with an embodiment of the present invention;

FIG. 1B shows that an uncompressed state of the switch in FIG. 1A opens an electrical network;

FIG. 1C shows that an compressed state closes the network and lights up the powered LED lights;

FIGS. 2A and 2B show the relation between the conductive mechanical metamaterial and a digital logic gate schematic:

FIG. 2C shows the combination of rotations of layer A and layer B in FIG. 2A defining digital input:

FIG. 3A shows kinematic tessellation tilings and rotation for bit assignment;

FIG. 3B shows Multistability by magnetoactive material compoites:

FIG. 4A shows a BUFFER switch;

FIG. 4B shows a NOT switch;

FIG. 5A shows a AND gate:

FIG. 5B shows a circuit schematic with serial switches for a AND gate:

FIG. 5C shows the conductive trace network for the metamaterial logic gate “AND”;

FIG. 5D shows a OR gate:

FIG. 5E shows a circuit schematic with serial switches for a AND gate:

FIG. 5F shows the conductive trace network for the metamaterial logic gate “OR”;

FIG. 6A shows an application of DeMorgan's laws to the conductive trace network involving reversal of the 0/1 bit assignment to create an NOR gate from an AND gate:

FIG. 6B shows an application of DeMorgan's laws involving horizontal or vertical mirroring of the conductive network to create an NOR gate from an AND gate;

FIG. 7A shows a digital logic gate schematic, truth table, schematic and photo of metamaterial logic gate, and realization of the truth table shown in photos for an OR gate:

FIG. 7B shows a digital logic gate schematic, truth table, schematic and photo of metamaterial logic gate, and realization of the truth table shown in photos for an XOR gate:

FIG. 8A shows an AND metamaterial gate in the central image, along with the 4 corresponding self-contact states due to combinations of applied:

FIG. 8B shows that modular mechanical metamaterial processors must transfer the electrical output as a mechanical configuration of rotation in this example:

FIG. 8C shows that for certain logic gate assemblies, substitution of the first gate with the first switch of the second gate leads to correct truth table (right bottom);

FIG. 9A shows a schematic of a full adder of 2-bit numbers:

FIG. 9B shows a metamaterial schematic of the full adder of 2-bit numbers using the philosophy in FIG. 8C:

FIG. 9C shows a photograph of a full adder of 2-bit numbers:

FIG. 9D shows representative binary and decimal inputs lead to correct output values from the metamaterial circuit;

FIG. 10A shows a logic diagram of a full adder separated into two logic outputs, Q_{Carry} and Q_{Sum};

FIG. 10B shows the truth table of the full adder logic operation;

FIG. 11 shows a diagram that describes the connection between the Boolean functions and the physical design of the full adder;

FIG. 12A shows a schematic and photograph of a 2-bit adder;

FIG. 12B shows a schematic and photograph of a 2-bit multiplier;

FIG. 12C shows a schematic and photograph of a 2-bit subtractor;

FIG. 13A shows a schematics of soft material integrated circuit sample with digitized mechanical inputs for a 2-bit adder;

FIG. 13B shows a schematics of soft material integrated circuit sample with digitized mechanical inputs for a 2-bit multiplier;

FIG. 13C shows a schematics of soft material integrated circuit sample with digitized mechanical inputs for a 2-bit subtractor;

FIG. 14A shows a schematics of half-depth cut of the metamaterial to release metastable rear memory block for memory that achieves new stable state based on output of front face digital logic computation where the back half uses magnetoactive material to maintain final compacted states; and

FIG. 14B shows experimental realization of half-depth cut digital logic metamaterial fabrication and stress application on realizing different front-to-back compacted states.

### DETAILED DESCRIPTION OF THE PRESENT INVENTION

### 1. The Concept of the Present Invention

Embodiments of the present invention provides digital information processing devices such as logic gates, integrated circuits, storage devices and methods of designing the same using soft materials that intrinsically respond to applied fields, including light, thermal gradients, mechanical load, electromagnetic waves, acoustic waves, humidity gradients, pH gradients, and/or other applied fields. The soft materials are prepared as a matrix of unit cells stacked and connected together with gaps.

Soft materials are materials with low bulk modulus, such as less than 1 GPa. Soft material may include but not limited to organic materials, organic compounds, inorganic materials, inorganic compounds, polymers, elastomers, epoxy-based composites, fiber-based composites, synthetic materials and other biological materials.

The surfaces or cross-sections of some of the unit cells are coated with traces of conductive soft materials. Conductive soft materials may include a composite mixture of a polymer or other aforementioned soft material filled with conductive filler material including carbon, gold, silver, copper, or other electrically conductive filler particles. The traces may also be fully encapsulated by the unit cells. The depth of the unit cells may or may not be used as a dimension of shape reconfiguration, and thus the depth may or may not be included as a design variable.

In an uncompressed configuration, the traces of conductive materials do not form a continuous network for electrical conductivity. In fully compact configurations, the traces of conductive materials might or might not form an electrically conductive network depending on the ways that the matrix is compressed.

In one embodiments, all of the unit cells are connected without any discontinuities. In this case, when the matrix in uncompressed, the electrical network is open. When the matrix is compressed under an applied load, the matrix shifts the form into a fully compact self-contact configuration and the electrical network is in a closed connecting state and is conductive.

In some embodiments, some of the unit cells are connected and there are some discontinuities between some other unit cells. In this case, when the matrix is compressed under an applied load, the matrix transforms into a number of distinct fully compact configurations dependent on the applied load on different layers of the matrix. The distinct fully compact configurations match the circuit for switches, logic gates, storage devices or integrated circuits.

The applied load may cause counterclockwise or clockwise rotation of some of the unit cells due to the gaps and the discontinuities. Discontinuities serve as a mechanism to govern internal motion of adjacent unit cells and layers. Clockwise/counterclockwise rotations can each be assigned a digital value serving as binary digital inputs. The design of the traces of the electrically conductive material and the configuration of the matrix including the manners that the unit cells are stacked and the locations of the discontinuities and are deigned in a way such that when the matrix is compressed, the output of the electrical network is in agreement with the corresponding output of the switches, logic gates, storage devices or circuit assemblies based on a corresponding Boolean functions or arithmetic expressions. Examples of the switches include BUFFER and NOT, etc. Examples of the logic gates include AND, OR, NOR, XOR, etc. Examples of the integrated circuits include an adder, a multiplier or a subtractor, etc.

In some embodiments, all of the unit cells are uniform so the stress applied on each layer will be uniform.

In some embodiments, the matrix is designed to include a number of columns and rows. The alternating rows are designed to be rotating layers including discontinuities.

In some embodiments, the logic gates or the integrated circuits can all be made using only BUFFER switches and NOT switches based on the standard sum of product (SSoP) formulation. The numbers of the rotating layers should be equal to the number of inputs. The number of columns should be equal to the number of minterms in the SSoP formulations. The switches in the same column are connected in series. All of the columns are then connected in parallel.

The concept of the present invention will be described in detail according to examples of specific designs.

The soft material integrated circuit design accepts digitized mechanical sensory input and outputs digitized electrical sensory output in power-of-two-based-permutation logic values, typical of modern digital computing. It is presumed that an analog-to-digital layer precedes the input stage and that a digital-to-analog output stage succeeds the output stage to better interface with common natural analog inputs and output fields, such as mechanical stress inputs and mechanical force outputs. The design of the soft material integrated circuits agrees with foundational principles of switching electrical networks, and their relationships with Boolean algebra expressions and associated truth tables.

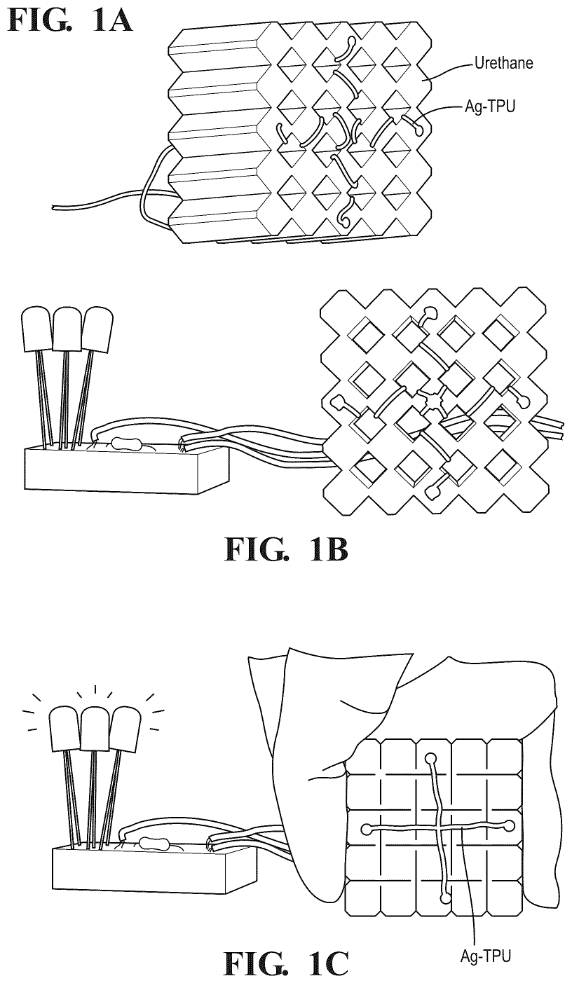

An example is shown in FIGS. 1A-1C to illustrate the principle of the present invention. As can be seen in FIG. 1A, the metamaterial is composed of a cellular elastomeric substrate with a conductive silver-thermoplastic polyurethane (Ag-TPU) trace network on one cross-section. The material unit is fabricated by casting urethane rubber in a mold, followed by application of the Ag-TPU network. In an uncompressed state, as shown in FIG. 1B, the electrical network is open so the LED lights are not lit. By compression of the metamaterial, the Ag-TPU trace network conducts at self-contact, closing a serial electrical network in FIG. 1C to provide the electricity to the LED lights.

Advancing this concept to functional digital logic requires more intricate mechanical configurations and corresponding electrical networks.

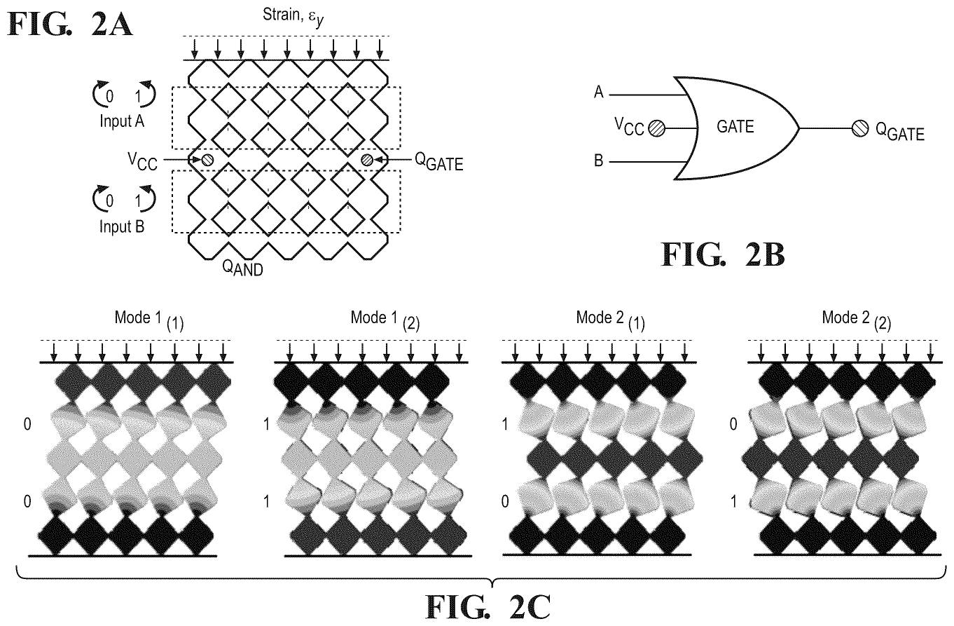

An example is shown in FIGS. 2A-2C. By exploiting higher order buckling induced by material discontinuities, 4 buckling modes that are associated with the 4 combinations of uniaxial and shear stress are realized, as shown in FIG. 2C.

In FIG. 2A, the shear and rotations of each layer A and B become the digital inputs. The (counter) clockwise rotations are (1) 0 binary inputs. The counterclockwise rotation is induced by mechanical shear to the left, while shear to the right induces the clockwise rotation of layer units. A modal analysis of buckling modes uncovers the combination of digital inputs—text at sides of FIG. 2C—that may be achieved.

Importantly, each buckling mode yields full compaction of the metamaterial and thus means for unique self-contact states. The conductive Ag-TPU trace networks are therefore applied to the mechanical metamaterial.

### 2. Building Blocks: BUFFER and NOT Switches

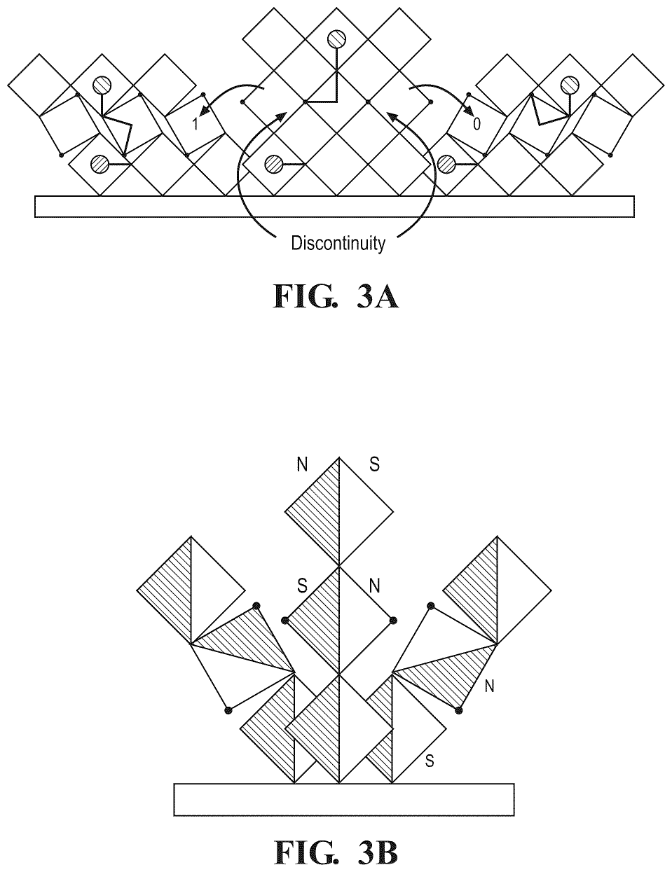

FIG. 3A more clearly shows kinematic tessellation tilings and rotation for bit assignment distinctions. The Ag-TPU network is designed to satisfy the assignment that counterclockwise rotation of the central square corresponds to a 1 digital bit, while clockwise rotation of the central square is a 0 digital bit, which agrees with the electrical once fabricated, counterclockwise rotation occurs due to left-ward shear, while clockwise rotation occurs due to right-ward shear. On the left, the network connects, while on the right, the network disconnects. These units are essentially realizations of the Buffer logic gate or NOT gate. A NOT gate is a mirrored Ag-TPU network of Buffer logic gate. Assembly, mirroring, and/or negation of these units is the process employed to realize the logic gates. Discontinuities will serve as a mechanism to govern internal sliding of adjacent units and layers.

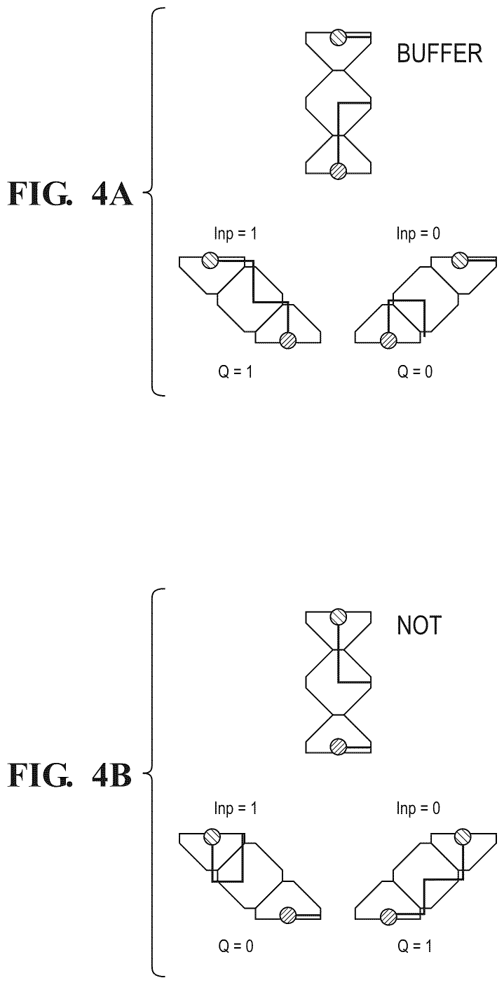

FIGS. 4A and 4B give a more clear picture of a BUFFER switch and a NOT switch used for composing any integrated circuit composition according to the standard sum of product (SSoP) formulation. The SSoP formulation will be described in detail later.

A BUFFER switch and a NOT switch are two types of switches that constitute the circuitry for all integrated circuit syntheses. Such switches are manifest in the present invention by a shared beam design that rotates either counterclockwise or clockwise as a result of digitized mechanical input. The inputs fully rotate each layer due to the application of layer-by-layer shear (sideways stress) inputs until the soft material is deformed in a self-contact configuration. A counterclockwise rotation is considered a mechanical input of ‘1’ resulting from shear to the left. A clockwise rotation is considered as a mechanical input of ‘0’, resulting from shear to the right. FIG. 4A illustrates the BUFFER switch conductive path design which conducts between the terminals (output Q=1) when the beam reaches self-contact in the counterclockwise rotation (Input=1). FIG. 4A is a representation of the soft material cross-section, where the grey shaded area is a non-conductive soft material substrate and the light grey lines represent a conductive soft material that is molded or otherwise fabricated in such as a way as to make a perfect bond with the substrate. Conversely. FIG. 4B illustrates an inverted BUFFER or a NOT which conducts (output Q=1) when it rotates clockwise (Input=0).

### 3. AND & OR Gates

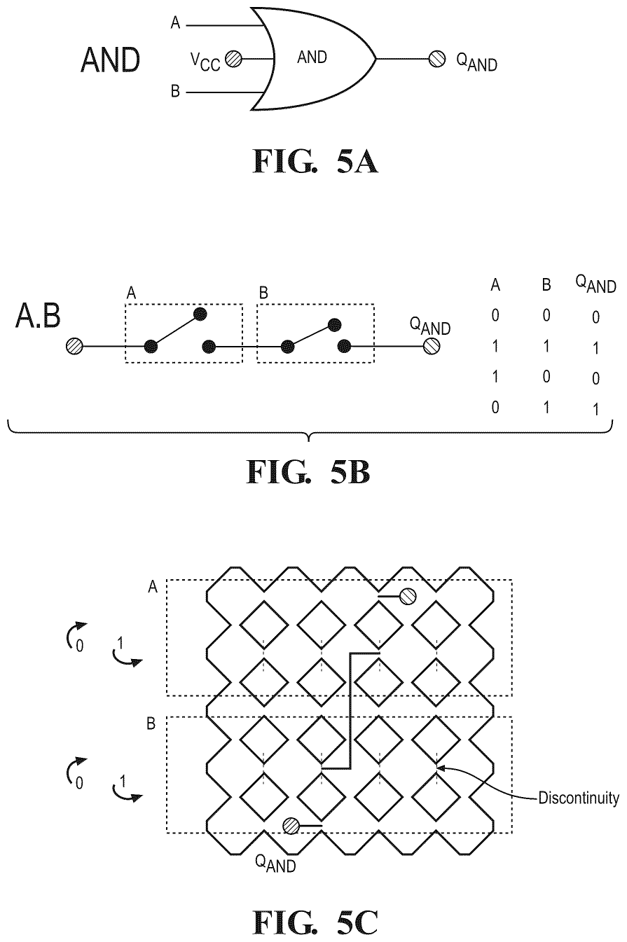

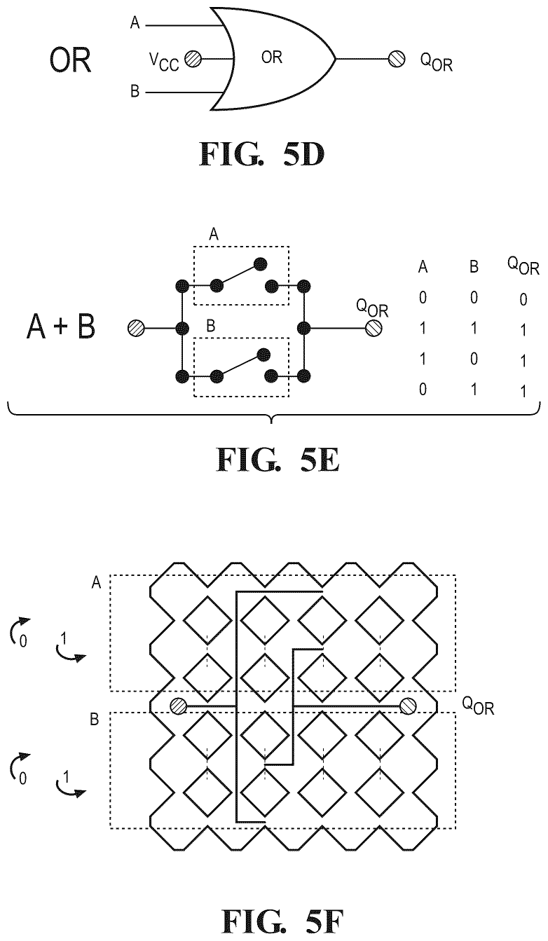

For AND and OR, the equivalent circuit schematics are shown in FIGS. 5B and 5E. Here, we find serial (AND) and parallel (OR) switch networks that intuitively agree with our understanding of how the AND and OR truth tables compute, FIGS. 5B and 5E. By exploiting discontinuities in the metamaterial design, shown in FIGS. 5C and 5F, along with stacked elemental switches, 4 buckling modes are induced corresponding to combinations of shear and uniaxial compression as shown in FIG. 2C. These modes open or close the switches according to (counter) clockwise assignment of (1) 0 digital bits via the Ag-TPU trace networks of FIGS. 5C and 5F. As a result, a clear analogy exists between the circuit schematics in FIGS. 5B and 5E and the corresponding mechanical metamaterial and trace network topology in FIGS. 5C and 5F.

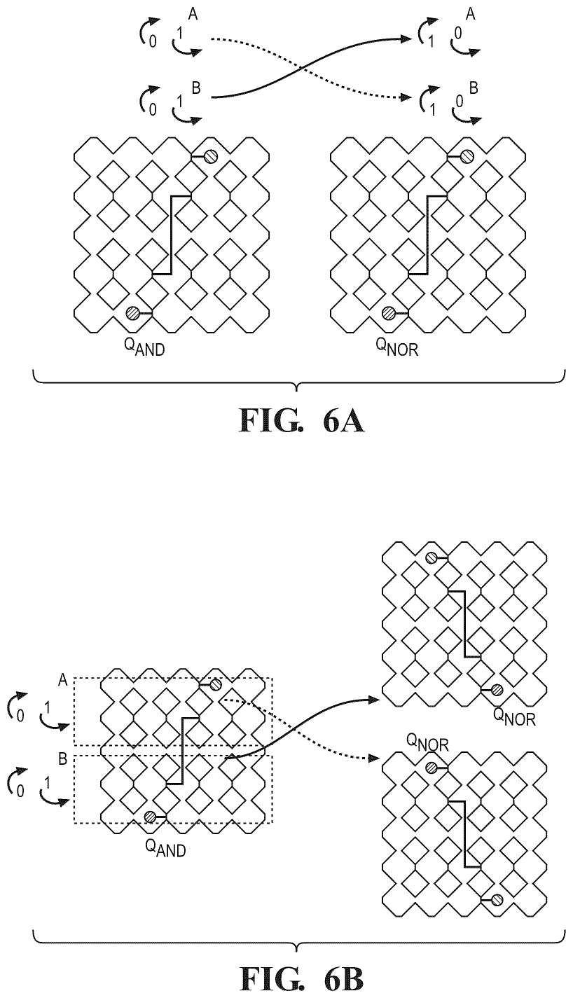

DeMorgan's theorem is applied to create the NOR and NAND logic gates. The implementation is exemplified for the AND to NOR relation in FIGS. 6A and 6B. By DeMorgan's theorem with the new conductive mechanical metamaterials, a NOR may be created from an AND by reversing the assignment of 0 and 1 digital bits FIG. 6A. As shown in FIG. 6B, this is analogous to mirroring the conductive network topology horizontally or vertically. These methods are exact because a change of bit assignment and mirroring mutually govern the relation between the buckling self-contact state and conductive network connectivity. Using the same approach, a NAND is created from an OR. Finally, negation is used to create a XOR from an OR-NAND serial circuit and to create a XNOR from an AND-NOR parallel circuit.

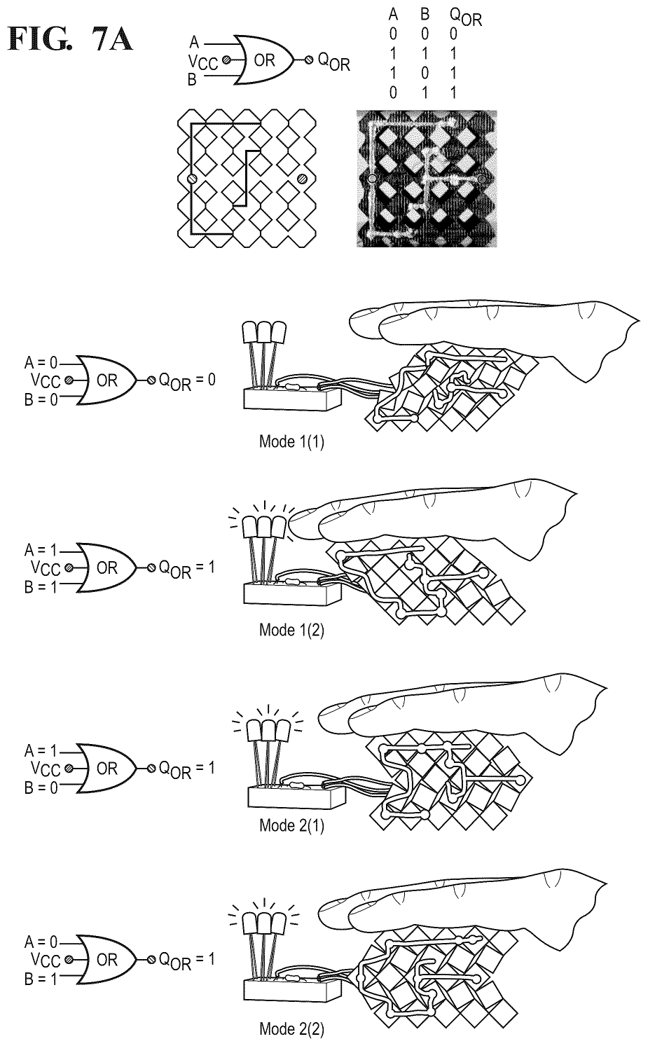

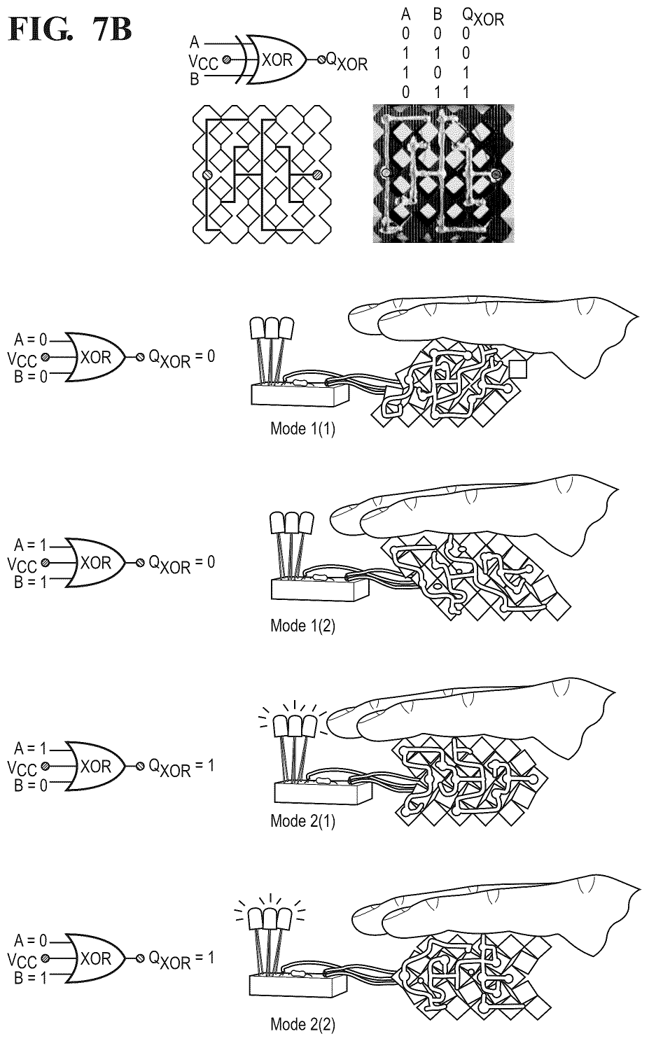

The Ag-TPU networks determined by this design process are shown for the OR and XOR gates in FIGS. 7A and 7B, respectively. The truth tables for the OR and XOR gates are shown at the top of each column of FIGS. 7A and 7B, while photos of the realization of these digital logic sequences are shown in the columns of FIGS. 7A and 7B, matching the conventional logic. All together, the design process is extensible to all logic gates (Buffer, NOT, AND, NAND, OR, XOR, NOR. XNOR).

### 4. Logic Gate Assemblies

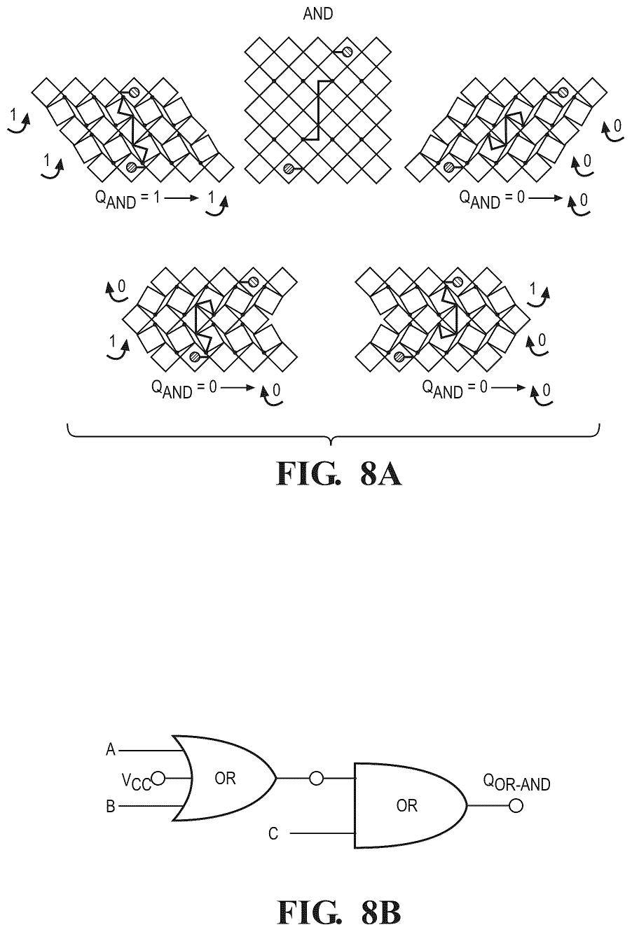

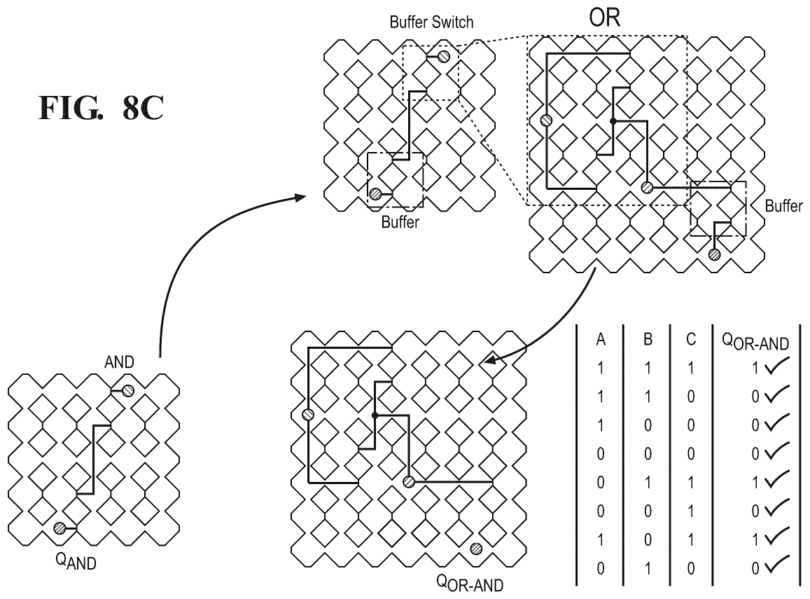

The technical challenge underlying conductive metamaterial logic gate assembly is scrutinized further in FIGS. 8A-8C. In FIG. 8A, an AND metamaterial gate unit is shown in the central image, along with the 4 corresponding self-contact states due to combinations of applied loads. To assemble this AND metamaterial gate unit with adjacent units, such as the OR gate in FIG. 8B, it is imperative that the final digital output Q, shown in FIG. 8A, must transmit as a corresponding mechanical layer rotation. For example, for an AND gate when the inputs are 1 and 0, the output to transfer to adjacent metamaterial gates must be a clockwise rotation (a 0 digital output). The challenge of assembly by mere stacking or layering of the current metamaterial logic gates is that input values are not always represented by corresponding digital output values. For instance, for the NAND gate when the inputs are 1 and 1, the output should be clockwise rotation (a 0 digital output) which is neither of the input values.

To overcome this technical challenge, assembly methods that have analogues in conventional integrated circuit design and logical syntheses are used.

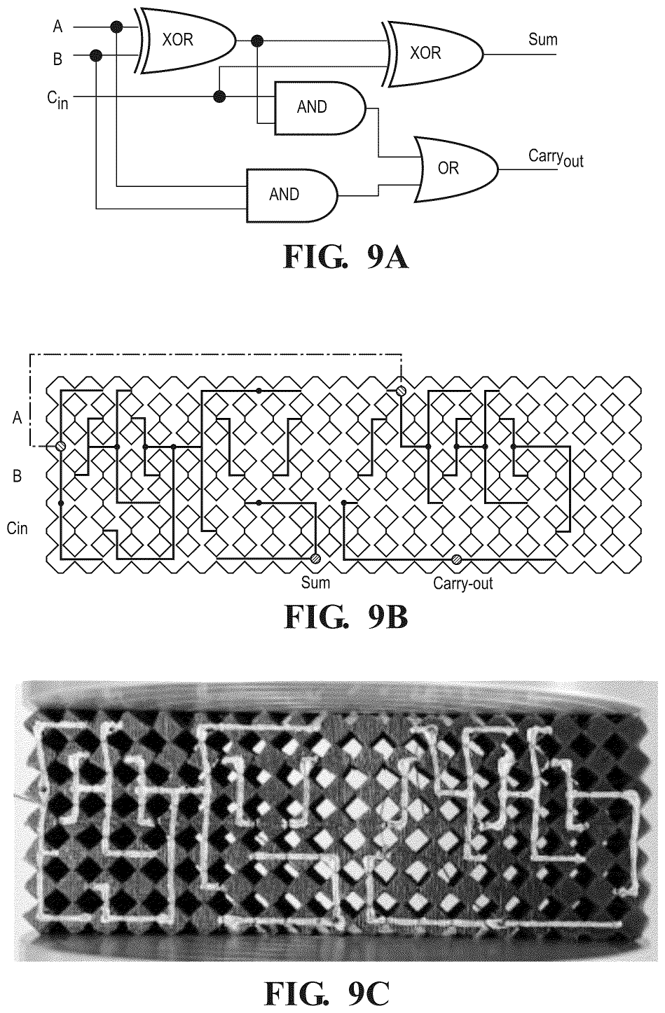

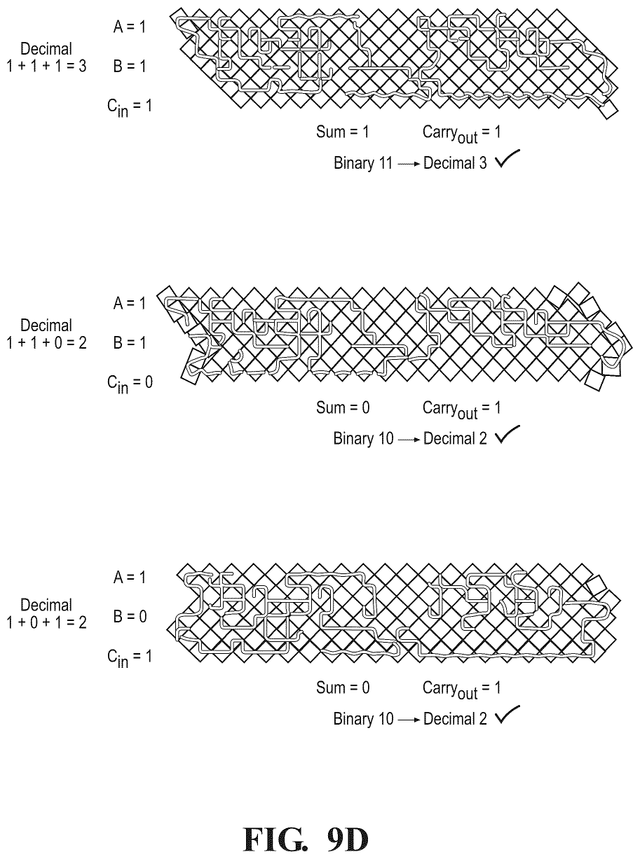

In their preliminary research, the inventors found that replacement of the first switch of the second gate with the first gate led to correct logic gate assembly if the first switch of the second gate was a Buffer gate, as shown in FIG. 8C. This coincidence was not substantiated except for a few example logic assemblies that succeeded in yielding correct truth tables. The Full Adder, as shown in FIG. 9A is another, and much more intricate, circuit for which this rule apparently applies. When the rule of switch-gate replacement is applied, the conductive mechanical metamaterial design and network connectivity in FIG. 9B are found. A sample is fabricated and then compressed and sheared in ways that corresponds to a 2-bit binary input. Three exemplary calculations are shown in FIG. 9C, which all agree with the respective decimal computation.

Present outputs for the assembly of such combinational circuits are the consequence of only present inputs. Using principles from logic design, including circuit equivalence and serial assemblies, a rule structure for conductive mechanical metamaterial logic gate assembly can be established. This will constitute a mapping between mechanical-electrical information transfer and network connectivity according to the canonical representations of logic gate assemblies from only ORs, ANDs, NOTs, and Buffers.

### 5. Canonical Boolean Functions

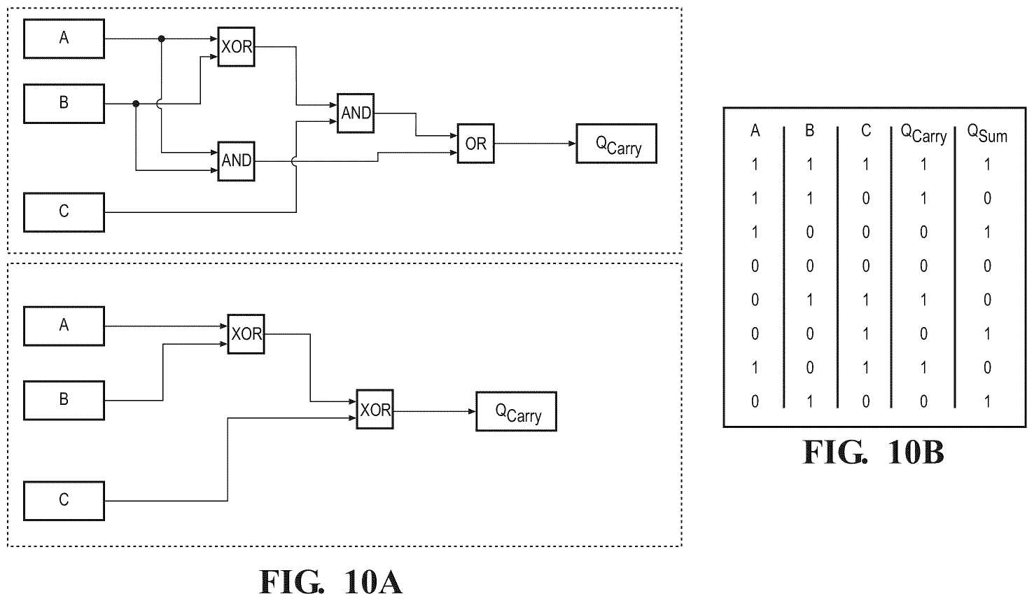

The basis of the soft material integrated circuit design is the set of canonical Boolean functions which constitute the overall architecture of the circuitry on the soft metamaterial surface. Thus, it would be beneficial to describe the methods used to extract such functions from specific logic operations. For instance, this section focuses on the full adder which is a fundamental addition operation found in all arithmetic computations. As shown in FIG. 10A, the full adder contains two 1-bit inputs that are added, A and B, and an additional carry input, C. The logical operation may be separated into two independent logical operations that output the Q_{Carry} and the Q_{Sum}. The truth tables for the outputs are shown in FIG. 10B.

Since these are simultaneous operations, a Boolean function can be determined for each output. The standard sum of product (SSoP) form of the canonical function is obtained by utilizing the truth table in FIG. 10B. The SSoP contains only AND and OR logic gate operations. For instance, an SSoP contains a minterm for each ‘1’ output. Each minterm contains the product (where products refer to AND logic gate operations) of all the input Boolean variables in that specific cell. If the input variable is ‘0’ in that specific cell, the inverted variable (˜) is included in that product, and vice versa. All the minterms are added (where additions refer to OR logic gate operations) to form the SSoP form of the Boolean function. The SSoP function for the Q_{Carry} and the Q_{Sum} are described by Eq. 1 and Eq. 2 respectively.

$$\\ \begin{matrix}{Q}_{Carry} = A \& B \& C \vert A \& B \& \tilde{C} \vert \tilde{A} \& B \& C \vert A \& \tilde{B} \& C & ( 1 )\end{matrix}$$

$$\\ \begin{matrix}{Q}_{Sum} = A \& B \& C \vert A \& \tilde{B} \& \tilde{C} \vert \tilde{A} \& \tilde{B} \& C \vert \tilde{A} \& B \& \tilde{C} & ( 2 )\end{matrix}$$

As shown in Eq. 1 and Eq. 2, both the Q_{Carry} and Q_{Sum} SSOP contain four minterms with each containing all the possible input variables (A, B and C). Yet, the quantity of minterms and variables may be optimized through function minimization techniques such as the Quine-McCluskey (QM) algorithm. By applying the QM algorithm, the modified QM SoP functions are obtained and demonstrated in Eq. 3 and Eq. 4.

$$\\ \begin{matrix}{Q}_{Carry} = B \& C \vert A \& C \vert A \& B & ( 3 )\end{matrix}$$

$$\\ \begin{matrix}{Q}_{Sum} = A \& B \& C \vert A \& \tilde{B} \& \tilde{C} \vert \tilde{A} \& \tilde{B} \& C \vert \tilde{A} \& B \& \tilde{C} & ( 4 )\end{matrix}$$

As shown by Eq. 3 the Boolean function for the Q_{Carry} output is significantly reduced, while the Q_{Sum} function in Eq. 4 remains identical to Eq. 2. Since the full adder operation only contains three inputs, it is possible that the SSoP is in its most optimized form as shown in the Q_{Sum}. Yet, for high order of inputs the QM algorithm reduces the Boolean function significantly as illustrated by Eq. 1 and Eq. 3 for Q_{Carry} output. As it will be shown in the next section, it is essential to minimize the Boolean function since it constitutes the quantity of switches and metamaterial cells required.

### 6. A Full Adder Design Using Soft Material Based on Canonical Boolean Functions

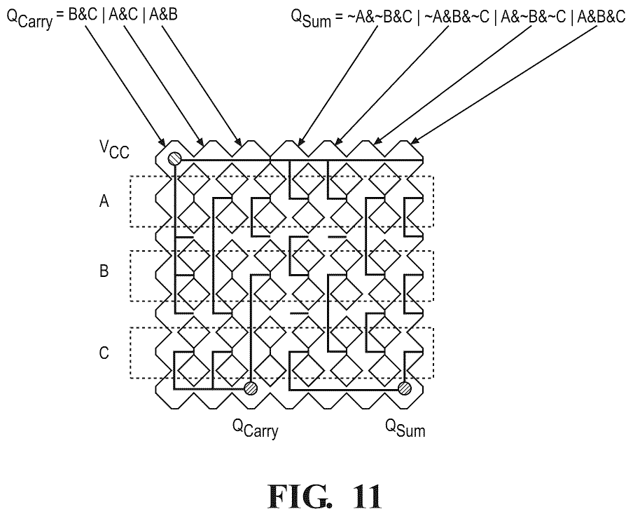

FIG. 11 is a diagram that describes the connection between the Boolean functions and the physical design of the full adder based on canonical Boolean functions using only BUFFER and NOT switches. To design the conductive network for a full adder, the optimized QM SoP functions and the two types of switches establish the overall circuitry. As shown in FIG. 11, the substrate contains three rotating layers in series that represent the three inputs of A, B and C. The Vcc node represents the electrical low voltage input, and the two red nodes represent the two outputs of Q_{Carry} and Q_{Sum}. The electrical circuitry path that can activate each output is constructed based on the respective Q_{Carry} and Q_{Sum} equation. For instance, the Q_{Carry} contains three minterms that are added (where the add operation represents the OR logic function) and thus it requires three substrate columns. The switches connected in series for each column are based on the minterm. For example, the initial minterm ‘B&C’ in the Q_{Carry} function is represented with the first column on the substrate with a BUFFER switch on the second and third row that are labeled B and C respectively. If a switch is inverted in the minterm, a NOT switch is placed on that row. All the columns are then connected in parallel. By utilizing such design technique, all the combinational logic operations may be programmed on the soft material cross-section, thus yielding the required substrate design and required soft conductive material designs for fabrication. The design method can be automated by utilizing MATLAB and Simulink software. The result is a soft material system that recognizes the application of mechanical stress, or pressure or force, and computes a programmed response associated with an appropriate reaction. This is an artificial sense of ‘touch’, blending sensory functions with both cognition and actuation responsiveness. For instance, the material could use functions such as addition, subtraction, and multiplication to respond proportionally, nonlinearly, or inversely with the applied mechanical inputs.

### 7. Realization of Exemplary Soft Material Integrated Circuits

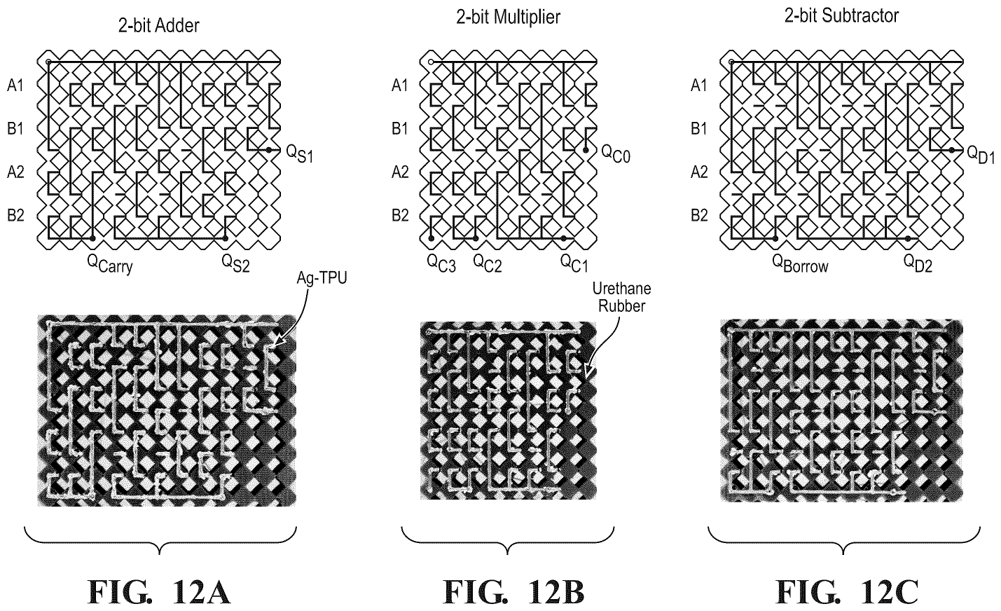

To realize exemplary soft material integrated circuits, the 2-bit adder, 2-bit multiplier, and 2-bit subtractor are designed and fabricated, as shown in FIGS. 12A-12C. The MATLAB automation program is utilized to generate the substrate design and overlayed conductive soft material network design. The elastomeric metamaterial substrates are fabricated by casting liquid urethane rubber (Smooth-On VytaFlex 60) in a two part mold. The mold parts are designed in CAD software SOLIDWORKS and 3D printed with the circuitry channels included. After the substrate is cured, the channels were filled with the Ag-TPU conductive ink by utilizing a syringe. The conductive ink utilized in the channels is a composite containing 35% (volume %, v %) silver (Ag) microflakes (Inframat Advanced Materials, 47MR-10F) and 65% (v %) thermoplastic polyurethane (TPU) elastomer (BASF Elastollan Soft 35 A) which bonds to the urethane rubber. The final samples are approximately a few inches in physical dimension in the cross-sectional spans and a few inches in the cross-sectional depth.

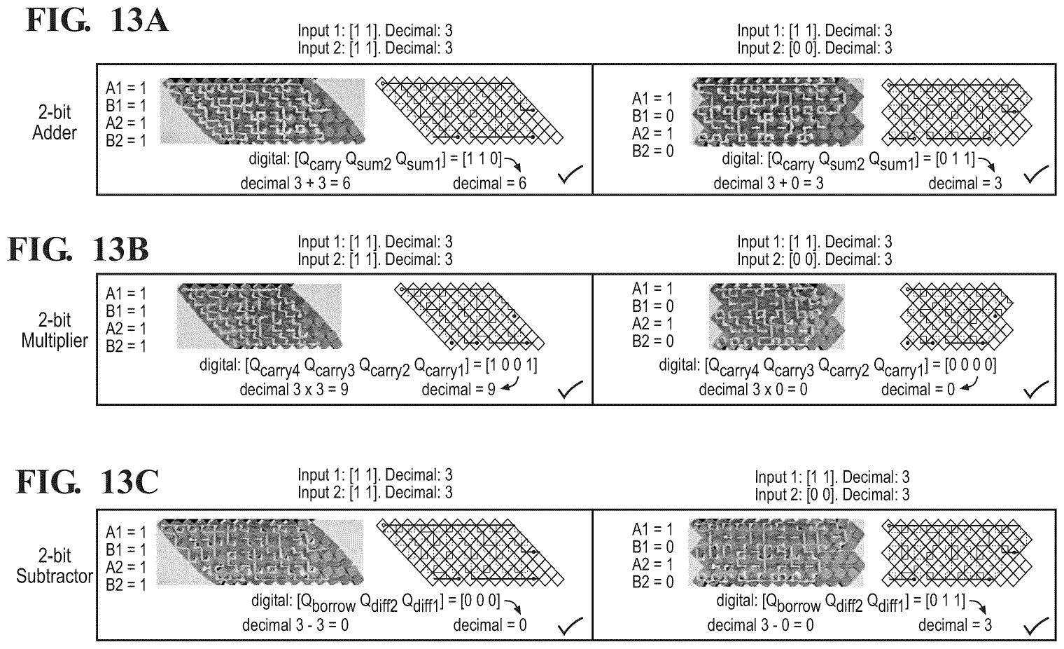

A sequence of demonstrations are conducted to exemplify the operation of the 2-bit adder, 2-bit multiplier, and 2-bit subtractor. As shown in FIGS. 13A-13C, the samples are compressed until they reach self-contact and the switches are connected appropriately. Each layer is sheared according to the input loading. In practice, an analog-to-digital converter layer is required to precede the application of shear, which is an area of future development. These are 4-layer specimens, requiring 4 inputs. As a result, there exist 16 different self-contact configurations associated with all input combinations in the corresponding truth table. FIGS. 13A-13C illustrate the ‘1111’ and the ‘1010’ configurations for each integrated circuit formulation. FIGS. 13A-13C show that the resulting digital output sequences agree with the decimal values for the associated arithmetic operation.

### 8. Extension of the Integrated Circuit to Optical Physics for a ‘Sight’ Sense

To extend the current foundation of integrated circuit design in soft materials to encompass responsiveness to optical cues for sake of a ‘sight’ sense requires incorporation of additional material domains that respond to light. One approach can be to use liquid crystal elastomers (LCEs), which are programmable materials that use lightly cross-linked polymers to reversibly respond to light, heat, and other solvent chemicals. Shape transformations may be programmed into the LCEs that are proportional to such thermal, optical, or chemical stimuli. To extend the current soft material integrated circuit design to optical physics, one could utilize a material fashioned from LCEs that are polarized in such a way as to respond to specific optical stimuli and thus close the associated conductive network to control the response. One example may be an opto-mechanical response, whereby an increasing brightness of light results in a proportional increase in the physical size of the material, based on the polarized wavelengths and the cumulative spectral content of the light application. In this way, the material would grow and shrink in a way similar to flower petals pursuing acquisition of sun for photosynthesis. Another example may be the use of LCEs that are programmed to recognize shapes, such as a square, circle, and triangle. When exposed to light giving such geometric patterns, the LCEs can appropriately deform according to a multiplicative sequence. This lends itself to a form of memory that would trigger the information processing layers to recognize the existence of a square object, or circular object, and so on.

### 9. Data Processing with Mechanical Memory

The aim of this section is to synthesize mechanisms of data storage and memory for the new class of soft, conductive integrated circuits based on soft material logic gates and integrated circuits discussed above.

One embodiment of memory utilizes magnetoactive materials. Magnetic polarizations of magnetoactive metamaterials are used to control mechanical properties and statically stable states. Multistability will be considered as a means to temporarily or permanently store digital outputs.

These materials will be explored as a means for conductive mechanical metamaterial memory modules according to polarization like that schematically shown in FIG. 3B. By curing the magnetoactive materials under a magnetic field, induced by magnets placed into the voids of the mold, the resulting materials will have a bias to maintain one of two compacted configurations corresponding to either left or right shear of the layer, FIG. 3B.

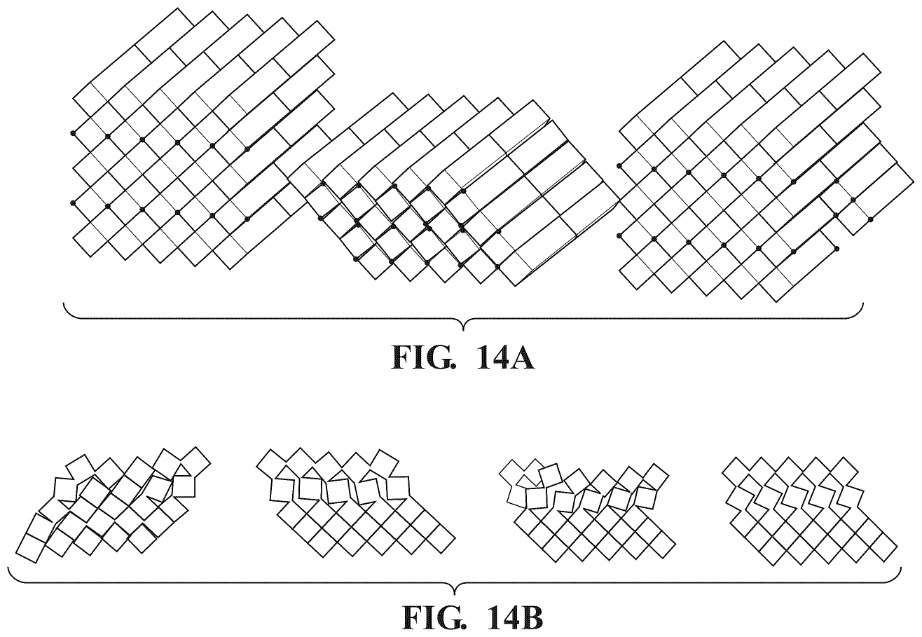

Using such magnetoactive layers, one can then create a foundation for memory blocks according to half depth fabrications at the output of logic circuits. The vision is shown in FIGS. 14A-14B. An output logic block will have a cross-sectional cut halfway through the depth, that separates front-to-back compacted states. With the back region fabricated from magnetoactive material polarized as described in the prior paragraph, the output of the logic sequence will be written into the memory block configuration via the stored stable state. Subsequent calls to the output will then draw from the mechanical-electrical state so as to send feedback into additional logic sequences.

The means to exploit magnetoactive material as a vehicle for memory and data storage has striking parallels to the original mode of data storage in modern computers: electromechanical hard drive disks with magnetic storage. We will begin by focusing on elementary sequential circuit synthesis, such as the classical Set-Reset Flip-Flop circuit. The Flip-Flop is effectively a latching circuit that uses a single bi-stable element to remember prior outputs, compare them to present inputs, and decide on a new output. Considering the combinational circuit constructs discussed in prior sections, the final output signal via signal transfer is re-used to account for either volatile or non-volatile retention of the output result. In other words, the magnetoactive memory module will first be considered simply as a volatile memory to drive the subsequent input of the SR Flip-Flop as the original use of the Flip-Flop resets in mechanical stress. This is how ratchets work, using circularly repeating motions to help drive the subsequent stable state. Next, the magnetoactive memory module is considered as a non-volatile block, so that the data can be called upon at any future time. This construct is more comparable to traditional memory in modern computers, which may be called without need for repeated use after each access. The future work will involve the search for analogues of keypad locks, data registers (directories), and counters in this new foundation of conductive mechanical metamaterials.

As will be clear to those of skill in the art, the embodiments of the present invention illustrated and discussed herein may be altered in various ways without departing from the scope or teaching of the present invention. Also, elements and aspects of one embodiment may be combined with elements and aspects of another embodiment. It is the following claims, including all equivalents, which define the scope of the invention.

1. A digital information processing device, comprising:
a soft material including a plurality of electrically conductive and electrically non-conductive regions, the soft material having a shape configured to transform from an uncompressed configuration to fully compact configurations under an applied load,
wherein the electrically conductive regions form electrical networks that are in a closed or open state dependent upon the applied load acting on the soft material.

2. The digital information processing device according to claim 1, wherein the closed or open state of the electrical networks corresponds to digital logic functioning,
wherein the digital logic functioning is in agreement with a preferred Boolean algebra function or arithmetic expression.

3. The digital information processing device according to claim 1, wherein the closed or open state of the electrical networks is representative of Boolean operations BUFFER and NOT,
whereby the shape transformation of the soft material closes or opens the electrical network of Boolean operations BUFFER and NOT according to the preferred Boolean function.

4. The digital information processing device according to claim 1, wherein digitized mechanical input conditions for the electrical networks are in the form of shear stress, mechanical force, mechanical pressure, thermomechanical loads, optomechanical loads, chemomechanical loads, electroactive material loads, and other body forces to yield the fully compact configurations of the device.

5. The digital information processing device according to claim 2, wherein a digital output sequence of the electrical networks corresponds to an output of the preferred Boolean function or arithmetic expression.

6. A digital information processing device, comprising:
a non-electrically conductive soft material substrate having a matrix of unit cells stacked together; and
traces of electrically-conductive soft material coated on a surface and/or applied inside some of the unit cells;
wherein the configuration of the matrix transforms into at least one fully compact self-contact configuration under an applied sideway load to compress the matrix;
wherein the traces form an electrical network in the fully compact self-contact configuration.

7. The digital information processing device according to claim 6, wherein a cross-section geometry of the device is constant,
wherein response to applied loads uniformly deforms each stacked unit cell, resulting in fully compact configurations.

8. The digital information processing device according to claim 6, wherein the unit cells are connected together in a configuration of repeating stacked layers with periodic gaps and without discontinuities, wherein the at least one fully compact self-contact configuration includes one fully compact self-contact configuration, wherein the electrical network is an electrically conductive network in the fully compact self-contact configuration.

9. The digital information processing device according to claim 6, wherein the electrical network includes variable open and closed states according to the distinct fully compact configurations of the stacked unit cells.

10. The digital information processing device according to claim 9, wherein the variable open and closed states of the electrical network are identical to the digital representations of output signals obtained from a Boolean algebra function or arithmetic expression, and
wherein inputs agree with the associated digitized inputs to the Boolean function or arithmetic expression.

11. The digital information processing device according to claim 6, wherein the electrical network is an elemental switch, the at least one fully compact self-contact configuration includes two fully compact self-contact configurations, the two fully compact self-contact configurations correspond to binary digital outputs, the binary digital outputs correspond to an open or closed state of the elemental switch.

12. The digital information processing device according to claim 11, wherein the elemental switch is a BUFFER or NOT switch.

13. The digital information processing device according to claim 11, wherein the unit cells are connected together in a configuration of stacked elemental switches with periodic gaps and with discontinuities, at least one fully compact self-contact configuration includes four fully compact self-contact configurations corresponding to 4 buckling modes due to a combination of clockwise rotation and counterclockwise rotation of rotating layers, 2-bit binary inputs are based on (counter) clockwise assignment of binary digital bits for the rotating layers, the four fully compact self-contact configurations correspond to binary digital outputs, the binary digital outputs correspond to variable open or closed states of the electrical network representative of Boolean operations of logic gates.

14. The digital information processing device according to claim 11, wherein the unit cells are stacked together in columns and rows with periodic gaps and with discontinuities, the rotating layer alternate and numbers of the rotating layers being equal to numbers of inputs, numbers of columns being equal to numbers of minterms in the standard sum of product (SSoP) formulations, the switches in the same column connected in series and the columns connected in parallel.

15. The digital information processing device according to claim 6, wherein the stresses exerted in the material result from shear stress, mechanical force, mechanical pressure, thermomechanical loads, optomechanical loads, chemomechanical loads, electroactive material loads, and/or other body forces.

16. The digital information processing device according to claim 6, wherein the soft material substrate and/or the electrically conductive soft material layers are composed of a material that intrinsically responds to applied fields, including light, thermal gradients, mechanical load, electromagnetic waves, acoustic waves, humidity gradients, pH gradients, and/or other applied fields.

17. A digital information processing device, comprising:
a soft material including a soft material substrate and an electrically conductive soft material layer disposed on or in the substrate, the soft material responds to applied stresses by creating an electrical network of the electrically conductive soft material layer, the electrical network having a variable connecting configuration, and
wherein the connecting configuration of the electrical network is in agreement with a preferred Boolean function or arithmetic expression.

18. The digital information processing device according to claim 17, wherein the stresses exerted in the soft material result from shear stress, mechanical force, mechanical pressure, thermomechanical loads, optomechanical loads, chemomechanical loads, electroactive material loads, and/or other body forces.

19. The digital information processing device according to claim 17, wherein the soft material substrate and/or the electrically conductive soft material layer are composed of a material that intrinsically responds to applied fields, including light, thermal gradients, mechanical load, electromagnetic waves, acoustic waves, humidity gradients, pH gradients, and/or other applied fields.

20. The digital information processing device according to claim 17, wherein the device is a logic gate or an integrated circuit or a storage device.
